(19) United States
(12) Patent Application Publication
(10) Pub. No.: US 2003/0153157 A1
(43) Pub. Date: Aug. 14, 2003

(54) Low energy ion implantation into SiGe

(76) Inventors: Majeed A. Foad, Sunnyvale, CA (US); Norma B. Riley, Dublin, CA (US)

Correspondence Address: APPLIED MATERIALS, INC., Legal Affairs Dept, P O Box 450A, Santa Clara, CA, 95054, US

(21) Appl. No.: 10/272,701

(22) Filed: Oct. 16, 2002

Related U.S. Application Data
(60) Provisional application No. 60/347,925, filed on Oct. 18, 2001.

(51) Int. Cl. H01L 21/336; H01L 21/04; H01L 21/425

(52) U.S. Cl. 438/305; 438/528

(57) ABSTRACT

A method comprising introducing a crystalline film with silicon germanium over the surface of a semiconductor substrate, and introducing a junction region by an implant of a dopant into the crystalline film. An apparatus comprising a semiconductor substrate having an active region and comprising a crystalline film comprising germanium in the active region, a gate electrode overlying the crystalline layer, and junction regions formed in the substrate adjacent opposite sides of the gate electrode.

### CROSS-REFERENCE TO RELATED APPLICATION

This application claims the benefit of the earlier filing date of United States Provisional Patent Application No. 60/347,925, filed on Oct. 18, 2001.

### BACKGROUND

1. Field

The invention relates to integrated circuits and more specifically to devices used in integrated circuits.

2. Background

As technologies in the integrated circuit arena advance, integrated circuit devices tend to get smaller. Moore's law predicts that integrated circuits tend to be doubled every 18 months. In terms of scaling a conventional integrated circuit device such as a transistor, the transistor tends to decrease in dimension. For example, the gate electrode of a transistor gets shorter so that it takes less time for electrons to transit the gate. In this manner, a transistor may be switched on and off faster and clock frequency increased. In addition to reducing the lateral dimensions of a gate electrode, other components of a transistor must also be scaled (e.g., reduced in size). For example, vertical dimensions such as transistor junctions (e.g., source and/or drain junctions) are scaled accordingly.

According to current technologies, transistor junctions are formed by implanting a dopant into a semiconductor substrate, such as implanting arsenic (As) into a substrate (and possibly a gate electrode) to form an N-type device and boron (B) to form a P-type device. In terms of junction formation, a current trend in high performance transistor devices is to offset deep junctions (e.g., source or drain junctions) from a gate electrode and extend the offset junction to an area of the substrate adjacent the gate electrode by junction extensions (e.g., source or drain extensions). Such extensions (or tips) are typically shallower than the offset junction counterpart and are formed by a low energy implant (e.g., low energy ion beam implantation).

Junctions are generally characterized by their depth, steepness and sheet resistance. Sheet resistance, Rₛ, may be represented as:

$${R}_{s} = \frac{1}{ne μ} , \qquad ( 1 )$$

where Rₛ is a measure of the sheet resistance, n is the concentration of dopant atom, e is the elementary charge (electron or hole), and μ is mobility of charge carriers in, for example, silicon.

The property of a dopant atom generally effects the implantation of the atom in terms of junction depth and junction characteristic. In terms of a junction characteristic such as resistivity, the activation of a dopant into a substrate is generally governed by its solid solubility. Solid solubility can be described as the amount of dopants that can be dissolved at a certain temperature in a substrate of, for example, silicon and can still be electrically active. A high value of solid solubility means there is more activation and thus lower resistance. Arsenic is generally considered a heavy atom and thus does not penetrate well into a semiconductor substrate such as a silicon substrate. Arsenic has a high solid solubility and therefore is favored in achieving N-type low resistivity shallow junctions. Boron, on the other hand, is a lighter atom that tends to penetrate deeper into a substrate than arsenic. In other words, boron forms deeper junctions and its solid solubility is lower than arsenic. What this means in terms of junction formation (e.g., device formation) is that boron presents challenges in achieving low resistivity shallow junctions. Increasing the solid solubility of boron should have the effect of increasing the dopant activation and lowering the resistivity of the junction.

One prior attempt to fabricate shallow junctions with boron is a technique involving a pre-amorphization implantation with atoms, such as germanium (Ge). In other words, a portion of a silicon substrate designated for transistor device fabrication, particularly P-type junction formation, is implanted with a heavy dose of germanium. The crystalline structure of silicon is disrupted, e.g., made amorphous, by the implantation of germanium. Such amorphization is typically confined to a narrow region of the semiconductor substrate near the surface. The role of pre-amorphised layer is to eliminate the scattering of boron atoms/ions into major crystallographic axes, i.e., channeling.

Once the substrate is amorphisized, boron is implanted into the substrate. Although boron is a relatively light atom, boron cannot penetrate as deep into the substrate, because of the presence of an amorphous layer. Thus, relatively shallow junctions may be formed.

The pre-amorphization method described above achieves desired shallow junctions for a P-type implant such as boron. However, the technique relies on the destruction and recreation of a crystalline structure. Accordingly, such technique lends itself to potential crystal defects which may lead to device performance degradation. In addition, pre-amorphisation does not impact the junction resistance positively (e.g., does not lower resistance), but often, and if the pre-amorphisation process is not optimized, such process leads to an increase in the junction resistance. What is needed is an improved method of forming shallow junctions, particularly useful with atoms of a lighter mass such as boron.

### SUMMARY

In one aspect, a method is described comprising introducing a crystalline film of silicon-germanium over the surface of a semiconductor substrate, and introducing a junction region by an implant of a dopant into the crystalline film. Such a method finds use in the formation of integrated circuit devices relying on PN junctions, such as transistor devices. In another aspect, an apparatus such as a transistor device is described formed in part in an active region comprising a crystalline film of silicon-germanium.

Compared to conventional silicon substrates, the presence of a crystalline film including silicon germanium acts to modify the junction characteristics associated with the penetration of dopant atoms through, for example, ion implantation. Since germanium is a heavier atom than silicon, the nuclear stopping power in silicon germanium is higher leading to reduced penetration by dopant atoms in silicon germanium and thus steeper junctions than with silicon alone.

The mobility of charge carriers is also greater in silicon germanium than in silicon alone. The greater mobility means junctions with lower sheet resistance. In terms of circuit device performance, reduced sheet resistance translates to improve drive currents and faster clock speeds.

Additional features, embodiments, and benefits will be evident in view of the figures and detailed description presented herein.

### BRIEF DESCRIPTION OF THE DRAWINGS

The features, aspects, and advantages of the invention will become more thoroughly apparent from the following detailed description, appended claims, and accompanying drawings in which:

FIG. 1 illustrates a cross-sectional side view of a structure that is a semiconductor substrate having an isolated device region and a silicon germanium film in an epitaxial layer formed on the substrate and a first operation of forming an elevated junction transistor according to an embodiment of the invention.

FIG. 2 shows the structure of FIG. 1 after the introduction of an epitaxial layer of silicon in an epitaxial layer in the device region.

FIG. 3 shows the structure of FIG. 2 after the oxidation of the epitaxial layer of silicon and the introduction of a gate electrode over the substrate.

FIG. 4 shows the structure of FIG. 3 after the introduction of junction extensions into the silicon-germanium epitaxial layer and the subsequent introduction of side wall spacers adjacent the gate electrode.

FIG. 5 shows the structure of FIG. 4 after the introduction of junction implant.

FIG. 6 is a graphical illustration of dopant concentration versus penetration depth.

### DETAILED DESCRIPTION

Techniques of forming junction regions are described as is an apparatus such as transistor device. In one aspect, the techniques are useful in transistor fabrication particularly in tailoring shallow junctions, including shallow junction extensions, by introducing a crystalline film of silicon germanium over the surface of a semiconductor substrate and introducing a junction region by an implant of a dopant into the crystalline film. In the case of a transistor, the introduction of a junction region into a crystalline film of silicon germanium formed on the substrate allows shallower implantation into the substrate that may be exploited in the form of a junction extension or tip. By forming transistors according to such a method, the performance of such transistors may be improved. Characteristics such as sheet resistance associated with the junction may also be improved and drain junction current increased to allow faster frequency devices.

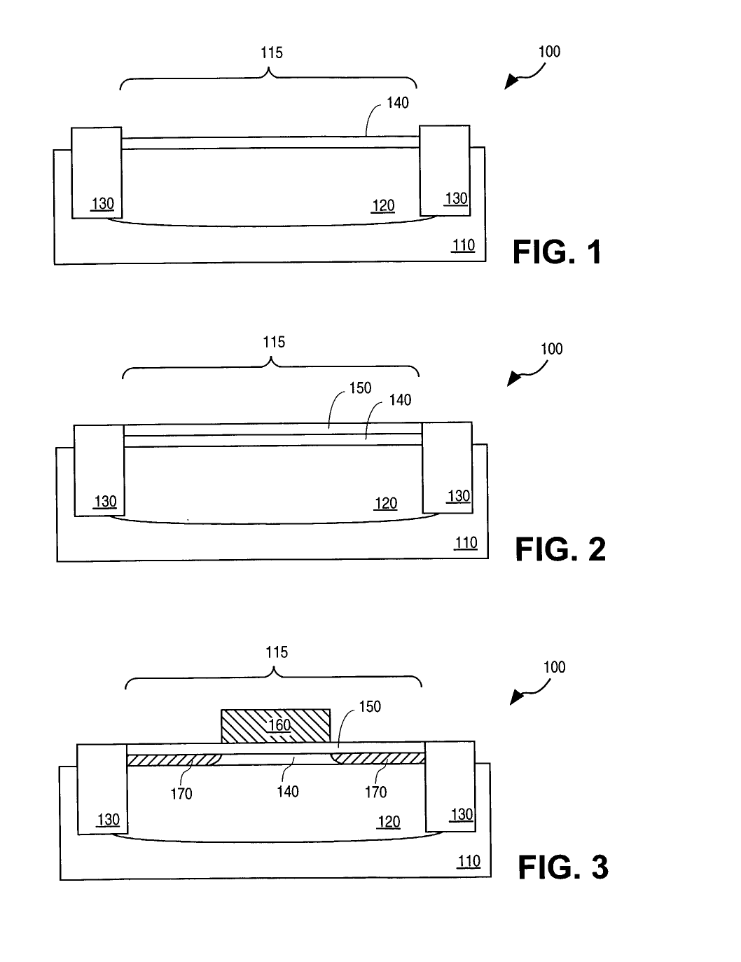

FIGS. 1-5 illustrate an embodiment of a method of forming a junction region. FIGS. 1-5 relate more specifically to the formation of an elevated junction transistor device. It is to be appreciated that the invention is not limited to elevated junction transistors or techniques of forming elevated junction transistors, but finds use in other applications where tailoring of junctions are important. The following description is thus representative of one such application.

FIG. 1 shows a cross-sectional side view of the structure that is, for example, a portion of a semiconductor wafer in which integrated circuits are formed. FIG. 1 shows structure 100 including substrate 110 of, for example, silicon. FIG. 1 also shows active device region 115 defined by isolation structures, such as shallow trench isolation (STI) 130. Although STI 130 is shown, other technologies such as local oxidation of silicon (LOCOS) structures or polysilicon encapsulated local oxidation of silicon (PELOX) structures are also suitable.

In the following embodiment, a P-type device is to be formed. Accordingly, substrate 110 is, for example, a P-type substrate having N-well 120 formed in active device region 115. The formation of N-well 120 follows conventional processing techniques.

Overlying the surface of substrate 110 and active device region 115 is silicon-germanium (SiGe) layer 140. In one embodiment, SiGe layer 140 is an epitaxially-grown crystalline layer. One way to form the epitaxial layer is to heat substrate 110, pass a gas mixture of silane (SiH₄) and germane (GeH₄) over the substrate and allow the Si and Ge molecules to grow on a surface of substrate 110. By adjusting the flow rate of the silane and germane gases and the temperature of the process, a uniform crystalline film of a desired ratio of silicon to germanium may be formed. A desired ratio is about 90 percent silicon and about 10 percent germanium to about 60 percent silicon and 40 percent germanium. One alternative to the described epitaxial growth process is to introduce Ge by implantation to the desired concentration such as by a heavy dose, low energy implant of Ge that does not destroy the crystalline structure of the silicon (i.e., does not amorphize).

Following the introduction of SiGe layer 140, FIG. 2 shows structure 100 after the introduction of silicon cap layer 150. Silicon cap layer 150 is, for example, an epitaxially-grown layer of crystalline silicon that, upon oxidation, a portion will act as a gate oxide separating a gate electrode from a channel region formed in substrate 110 below the gate electrode. Thus, after the introduction of silicon cap layer 150, such layer is oxidized by, in one embodiment, exposing structure 100 to an oxygen ambient (e.g., dry oxidation at about 900° C.) to form an SiO₂ layer. A typical thickness of the SiO₂ layer is on the order of 100 Å or less.

FIG. 3 shows structure 100 after the introduction and patterning of gate electrode 160 over oxidized silicon cap layer 150. In one embodiment, gate electrode 160 is polysilicon introduced and patterned according to conventional techniques such as chemical vapor deposition and photolithographic etch patterning.

Once gate electrode 160 is introduced, junction extensions are introduced through, in one embodiment, ion implantation. In this example, the junction extensions are aligned to the edges (i.e., side walls) of gate electrode 160. The implantation will easily penetrate oxidized silicon cap layer 150 to form the junction extensions in SiGe layer 140.

In forming a P-type device, a dopant such as boron is introduced through ion implantation. As noted above, boron is a heavy atom that has a tendency to penetrate or diffuse into silicon. The prior introduction of SiGe layer 140 as an epitaxial film increases the stopping power of the substrate. The stopping power is directly related to the rate of energy loss of an atom as it penetrates through a solid. Increasing the stopping power of a substrate means that an atom loses its penetration energy sooner as it penetrates. Boron penetrating into SiGe will lose its energy more quickly than boron penetrating into silicon alone. In this manner, the depth of boron penetration can be minimized and the depth of junction extensions 170 can likewise be minimized.

A second way to minimize the penetration depth of a dopant such as boron into a silicon substrate is by lowering the implantation energy. Thus, in one embodiment, contemplates an energy implant of boron into the SiGe layer 140 of no more than 2000 electrons-volts (eV), and more preferably less than 1000 eV. For example, a boron implantation energy of 500 eV into SiGe layer 140 yields a junction extension depth on the order of about 40 nanometers (nm).

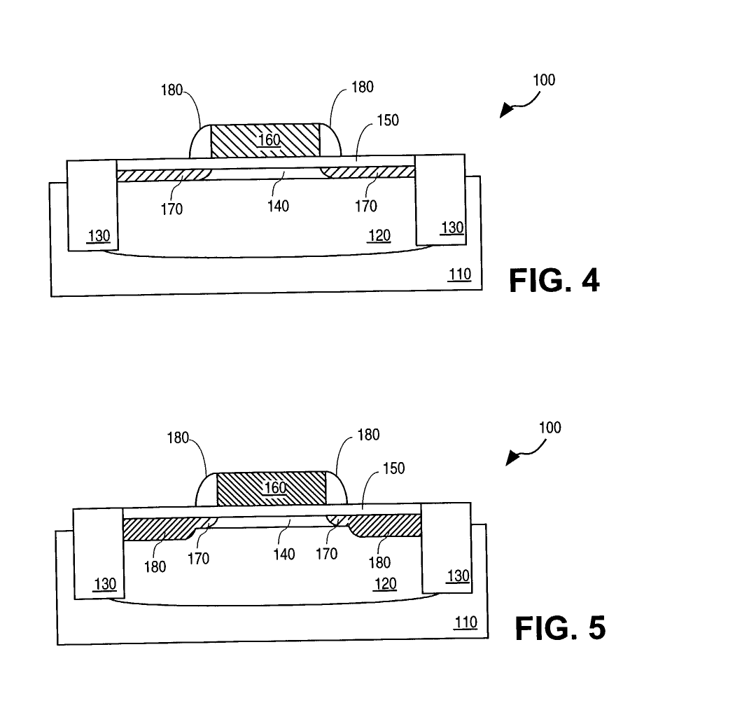

Once junction extensions 170 are formed in active device region 115, FIG. 4 shows structure 100 after the introduction of side wall spacers 180 formed on substrate 110 adjacent gate electrode 160. Side wall spacers 180 are formed according to conventional techniques to a thickness desired for, in one instance, separating the offset junction region(s) from the area of substrate 110 directly adjacent gate electrode 160.

FIG. 5 shows structure 100 after the formation of offset junction regions 180 in active device region 115 of substrate 110. Offset junction regions 180 are formed, in one instance, according to ion implantation techniques. The same implantation may be used in one embodiment to dope gate electrode 160.

FIG. 5 shows structure 100 of a transistor including gate electrode 160, offset junction regions 180, and junction extensions 170 as an extension of offset junction regions 180, junction extensions 170 formed in SiGe layer 140 adjacent gate electrode 160. In this instance, junction extensions 170 are formed on each side of gate electrode 160, i.e., extensions for both source and drain junctions. It is to be appreciated, that as known in the art, such extension may be limited to one junction, e.g., a drain junction, depending upon the desired device performance. In such case, conventional masking techniques may be used, for example, to modify the dopant profile.

As noted above, forming an elevated junction transistor utilizing an epitaxial SiGe layer formed over an active region of the substrate improves the stopping power of the substrate and thus provides control of junction depths of a dopant implant into substrate. In the case of a relatively light dopant such as boron, the light constituent has a tendency to penetrate deep into the substrate making the formation of, for example, shallow junction extensions or tips difficult to manage. The silicon-germanium layer increases the stopping power of the substrate supporting shallow junction formation.

In addition to increasing the stopping power on the substrate, the silicon-germanium layer, such as SiGe layer 140, enables faster mobility of charge carriers through the material which improves the sheet resistance of the junction (see Equation (1) above), thus increasing the performance of a device, such as a transistor device. SiGe layer 140 in the transistor device illustrated in structure 100 decreases the sheet resistance in the junction thus affording improved device performance.

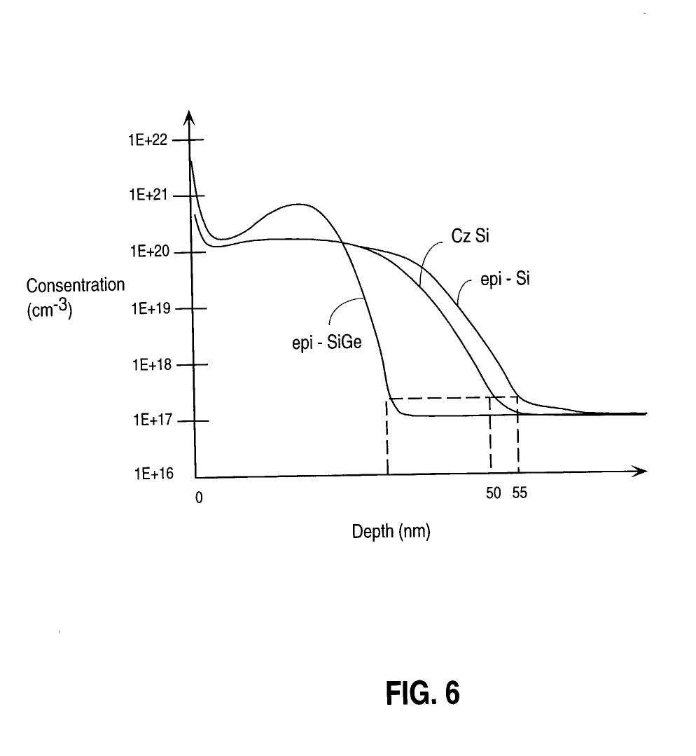

In addition to the above benefits offered by an epitaxial layer utilized, for example, in a device such as, for example, an elevated junction transistor, a silicon-germanium layer such as SiGe layer 140 also modifies the dopant distribution in such a way that the performance of the device is also increased. FIG. 6 shows a graphical comparison of a boron ion implantation of 5×10¹⁴ ions of boron into (1) Czochralski (Cz) silicon, (2) crystalline silicon, and (3) an epitaxial layer of silicon-germanium. FIG. 6 charts dopant concentration versus penetration depth into the three structures. Thus, a zero depth represents the surface of either silicon or the silicon-germanium and a depth of, for example, 60 nm represents a depth of 60 nm into the bulk of either silicon or the epitaxial layer.

As shown in FIG. 6, the dopant penetration distribution into silicon-germanium drops off much more sharply than the dopant penetration distribution into crystalline silicon (e.g., less straggle). Thus, the dopant distribution profile of silicon-germanium is much sharper than the profile of either Cz-silicon or epitaxial silicon. According to this illustration, the dopant distribution throughout the depth of the doped region is similar for silicon germanium, on the order of 1×10²⁰ atoms/cm³, while the distribution in Cz-silicon and epitaxial-silicon varies between 1×10²⁰ and 1×10¹⁸ atoms/cm³ or less. A more consistent dopant distribution throughout a doped region improves junction performance. Ideally, for best performance, the dopant profile should be vertical at its terminal penetration point.

It is known that epitaxially-grown silicon contains less carbon and oxygen contaminants than Cz-silicon. By implanting the dopants such as boron or arsenic into epitaxial grown silicon with low energy (e.g., less than or equal to 2000 eV), and by subsequent annealing, most of the dopants will activate since the likelihood of forming inactive complexes with oxygen and carbon is much less than in Cz-silicon. Therefore, a lower sheet resistance can be obtained epitaxially from wafers compared to Cz-silicon. In the example shown in FIG. 6, 500 eV of boron implanted at an ion concentration of 5×10¹⁴ cm⁻² implant concentration and a subsequent anneal at 1050° C. for one second gave a sheet resistivity of approximately 136 ohms per square (Ω/□) in epitaxially-grown silicon compared with 565 Ω/□ for Cz-silicon, with each substrate having a junction depth of 50-55 nm at a dopant concentration of 1×10 cm⁻³.

Another advantage of incorporating epitaxially-grown silicon on wafers is that such epitaxially-grown silicon is not generally subjected to chemical-mechanical polishing prior to device formation as is typical with Cz grown wafers. In general, chemical-mechanical polishing introduces surface defects potentially resulting in non-uniform native oxide surfaces in terms of, for example, gate oxide. Epitaxially-grown silicon over, for example, a silicon wafer has generally provided a more uniform (i.e., less defective) silicon surface on a substrate. After an implantation and subsequent anneal to activate the dopant, the spatially uniformly distributed dopants will activate uniformly, thus giving very high within wafer uniformity (typically, less than or equal to 1 percent).

As described above, the carrier mobility in silicon-germanium is much higher than that of silicon as is the stopping power of the substrate to a dopant. Thus, for the implant condition noted above, the junction depth into epitaxially-grown silicon-germanium is shallower (on the order of above 35-40 nm) than the junction depth into epitaxially Cz-silicon or epitaxially-grown silicon, but the sheet resistance is 133 Ω/□, comparable to that in epitaxially-grown silicon.

In the preceding detailed description, the invention is described with reference to specific embodiments thereof. It will, however, be evident that various modifications and changes may be made thereto without departing from the broader spirit and scope of the invention as set forth in the claims. The specification and drawings are, accordingly, to be regarded in an illustrative rather than a restrictive sense.

We claim:

1. A method comprising:
forming a crystalline film of silicon germanium over the surface of a portion of a semiconductor substrate, the portion comprising a first conductivity type; and
forming a junction region by an implant of a dopant of a second conductivity type into the crystalline film.

2. The method of claim 1, wherein forming a crystalline film comprises:
at least one of epitaxially growing the crystalline film and implanting germanium into the semiconductor substrate to form the crystalline film.

3. The method of claim 1, wherein the junction region is a first junction region and prior to forming the first junction region, introducing a structure over the substrate, and the method further comprises:
forming a second junction region into the substrate of the second conductivity type,
wherein the second junction region is positioned a greater distance from the structure than the first junction region.

4. The method of claim 3, wherein a portion of the first junction region overlies the second junction region.

5. The method of claim 1, wherein the dopant is implanted at an energy of 500 electron-Volts or less.

6. A method of forming a transistor device comprising:
forming a crystalline film of silicon germanium in a surface of the semiconductor substrate;
forming a first junction region into the crystalline film substrate proximally adjacent an area for a gate electrode on the semiconductor substrate; and
forming a second junction region into the crystalline film,
wherein the second junction region introduced to a depth that is greater than the first depth and in an area at a greater distance to the area for the gate electrode than the first junction region.

7. The method of claim 6, wherein forming a crystalline film comprises:
at least one of epitaxially growing the crystalline film and implanting germanium into the semiconductor substrate to form the crystalline film.

8. The method of claim 6, wherein the first junction region is an extension of the second junction region.

9. The method of claim 8, wherein the first junction region overlies a portion of the second junction region.

10. The method of claim 6, wherein forming a first junction region comprises:
implanting a dopant at an energy of 500 electron-Volts or less.

11. The method of claim 6, further comprising:
introducing a crystalline film of silicon over the crystalline film of silicon germanium;
oxidizing the crystalline film of silicon.

12. The method of claim 11, further comprising:
introducing a gate electrode over the oxidized film of silicon in the area for the gate electrode.

13. An apparatus comprising:
a semiconductor substrate having an active region and comprising a crystalline film comprising germanium in the active region;
a gate electrode overlying the crystalline layer; and
junction regions formed in the substrate adjacent opposite sides of the gate electrode.

14. The apparatus of claim 13, wherein the junction regions comprise first junction regions aligned to the apparatus further comprising a second junction region formed in the substrate and offset from one of the opposite sides of the gate electrode.

15. The apparatus of claim 14, wherein the second junction region overlaps a portion of one of the first junction regions.

16. The apparatus according to claim 15, wherein the first junction regions extend a first depth into the substrate and the second junction region extends a greater second depth into the substrate.

17. The apparatus of claim 13, the substrate further comprising an oxidized epitaxial silicon layer disposed between crystalline film comprising germanium and the gate electrode.
